(19) United States
(12) Patent Application Publication
(10) Pub. No.: US 2025/0337345 A1
(43) Pub. Date: Oct. 30, 2025

(54) Systems and Methods for Generating Power From Martine Environment Thermal Gradients

(71) Applicant: Alliance for Sustainable Energy, LLC, Golden, CO (US)

(72) Inventors: Julian David OSORIO RAMIREZ, Arvada, CO (US); Prashant SAINI, Lakewood, CO (US); Frederick Ralph DRISCOLL, Arvada, CO (US)

(21) Appl. No.: 19/189,606

(22) Filed: Apr. 25, 2025

Related U.S. Application Data
(60) Provisional application No. 63/638,717, filed on Apr. 25, 2024.

(51) Int. Cl. H02N 11/00; B63B 35/44; B63B 39/03

(52) U.S. Cl. CPC H02N 11/002; B63B 35/44; B63B 39/03; B63B 2035/4433

(57) ABSTRACT

Systems and methods for generating electrical power from marine environment thermal gradients. The systems and methods include a buoyancy-driven submersible designed to harness ocean thermal gradients to produce electrical power using thermoelectric generators and phase change materials. The buoyancy-driven submersible is configured to travel vertically in reciprocating motion across a temperature gradient between different depths of a body of water along a cable.

### CROSS-REFERENCE TO RELATED APPLICATIONS

This application claims benefit of, and priority to, U.S. Provisional Application No. 63/638,717, filed on Apr. 25, 2024, the entire contents of which are specifically incorporated by reference herein.

### STATEMENT REGARDING FEDERALLY SPONSORED RESEARCH OR DEVELOPMENT

This invention was made with government support under Contract No. DE-AC36-08GO28308 awarded by the Department of Energy. The government has certain rights in this invention.

### FIELD OF THE DISCLOSURE

This disclosure relates to systems and methods for harnessing thermal gradients in marine environments to produce electrical power, including electrical power for offshore power consumption applications such as aquaculture farms.

### BACKGROUND

Offshore power consumption applications, such as aquaculture farms, unmanned underwater vehicles, offshore platforms, underwater energy storage devices, water desalination stations, energy carrier production stations, and environmental sensors, often require significant energy requirements for their operation. For instance, offshore aquaculture farms require energy to power monitoring and maintenance equipment, circulation pumps, feeding systems, navigation lighting, and other operations. These energy requirements could range between 4 and 700 M Wh per year, depending on the farm size, location, and operating conditions. Currently, most aquaculture farms are powered by diesel generators, which increase operational costs and have a negative impact on the air and water.

There remains an urgent need in the art for less expensive and environmentally friendly technologies to generate power in marine environments for aquaculture farms and other applications. Such technologies would ideally leverage natural resources to provide sustainable sources of clean energy to these offshore applications.

### SUMMARY

Embodiments of the disclosure include systems and methods for generating electrical power from a marine environment thermal gradient.

An exemplary embodiment of the disclosure is a system for generating electrical power from a marine environment thermal gradient, which comprises:
a cable extending vertically between a lesser depth and a greater depth of a body of water; and
a buoyancy-driven submersible configured to travel vertically in reciprocating motion between the lesser depth and greater depth of the body of water along the cable;
wherein the buoyancy-driven submersible comprises:
   a hull comprising an exterior surface configured to contact the water and an interior surface defining an internal volume of the buoyancy-driven submersible;
   a plurality of thermoelectric generators disposed on the interior surface of the hull;
   a phase change material disposed within the internal volume of the buoyancy-driven submersible and in thermal communication with the plurality of thermoelectric generators;
   a battery electrically connected to the plurality of thermoelectric generators; and
   a buoyancy control mechanism.

Ocean thermal gradients, especially prevalent in mid-latitude regions, exhibit temperature differences between surface and deep waters ranging from 7° C. to 30° C., depending on seasonal variations. Systems and methods of the disclosure include a buoyancy-driven submersible designed to harness ocean thermal gradients to produce electrical power using thermoelectric generators (TEGs) and phase change materials (PCMs). The buoyancy-driven submersible is configured to travel vertically in reciprocating motion across a temperature gradient between different depths of a body of water along a cable.

The disclosed technology can provide autonomous power to offshore power consumption applications, such as aquaculture farms, unmanned underwater vehicles (UUVs), offshore platforms (such as for illumination), water desalination stations, energy carrier production stations (such as for hydrogen or ammonia), and ocean sensors, significantly reducing dependence on fossil fuels. The systems and methods of the disclosure utilize TEGs to convert thermal energy from marine environment temperature gradients into electrical power, while PCMs are employed to store and regulate this energy, capable of ensuring a stable and continuous power supply according to many embodiments. In some embodiments, systems and methods of the disclosure can offer large-scale power generation, such as in the range of 1-5 M Wh year.

The buoyancy-driven mechanism of the submersible enhances its capability to navigate through varying depths, optimizing its exposure to thermal gradients and maximizing energy harvesting. By demonstrating the feasibility and sustainability of using ocean thermal gradients for energy generation, this disclosure contributes to the broader efforts of integrating renewable energy technologies into harsh, remote marine environments. Implementing the disclosed systems will not only support environmental sustainability but also deliver significant advancements in the autonomy of marine operations.

### BRIEF DESCRIPTION OF THE DRAWINGS

Some embodiments of the disclosure are illustrated in the accompanying figures. The embodiments and figures disclosed herein are illustrative rather than limiting.

FIG. 1 illustrates an exemplary system of the disclosure.

FIG. 2 illustrates (a) a buoyancy-driven submersible and (b) a cross-section of a buoyancy-driven submersible showing various internal components: TEGs disposed on the interior surface of the hull and a PCM in the center of the buoyancy-driven submersible, according to some aspects of the disclosure.

FIG. 3 illustrates a cross-section of an exemplary buoyancy-driven submersible, including its buoyancy control mechanism.

FIG. 4 illustrates (a) a cross section of a portion of a buoyancy-driven submersible, and b) a heat flow diagram through that portion of the buoyancy-driven submersible, according to some aspects of the disclosure.

FIG. 5 includes graphs illustrating calculated energy generated by a single buoyancy-driven submersible and dive time as a function of volume, according to some aspects of the disclosure.

FIG. 6 is a graph illustrating results of a grid independence study for three different grid elements as discussed in Example 2.

FIG. 7 is a graph illustrating results of a time independence study for five different time step sizes as discussed in Example 2.

FIG. 8 is a graph illustrating power generation by TEGs with respect to time in Example 2.

FIG. 9 is a graph illustrating efficiency of TEGs with respect to time in Example 2.

FIG. 10 is a graph illustrating current produced by TEGs with respect to time in Example 2.

FIG. 11 is a graph illustrating voltage produced by TEGs with respect to time in Example 2.

### DETAILED DESCRIPTION

Reference will now be made in detail to various exemplary embodiments. The following detailed description provides a fuller understanding of certain embodiments, features, and details of aspects of the disclosure, and should not be interpreted as limiting the scope of the disclosure.

The embodiments described herein should not necessarily be construed as limited to addressing any of the particular problems or deficiencies in the art discussed herein. References in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to include such feature, structure, or characteristic in other embodiments whether or not explicitly described.

In order for the present disclosure to be more readily understood, certain terms are first defined below. Additional definitions for the following terms and other terms may be set forth throughout the specification.

As used herein, the term “about” is used to indicate that exact values are not necessarily attainable. Therefore, the term “about” is used to indicate this uncertainty limit. In some embodiments of the disclosure, the term “about” is used to indicate an uncertainty limit of less than or equal to ±20%, ±15%, ±10%, ±5%, or ±1% of a specific numeric value or target. In some embodiments of the disclosure, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

As used herein, the singular forms “a,” “an,” and “the” include plural references unless the context clearly dictates otherwise. For example, reference to “a cable” or “a buoyancy-driven submersible” includes one or more cables or buoyancy-driven submersibles, respectively.

An exemplary embodiment of the disclosure is a system for generating electrical power from a marine environment thermal gradient, which comprises:
a cable extending vertically between a lesser depth and a greater depth of a body of water; and
a buoyancy-driven submersible configured to travel vertically in reciprocating motion between the lesser depth and greater depth of the body of water along the cable;
wherein the buoyancy-driven submersible comprises:
   a hull comprising an exterior surface configured to contact the water and an interior surface defining an internal volume of the buoyancy-driven submersible;
   a plurality of thermoelectric generators disposed on the interior surface of the hull;
   a phase change material disposed within the internal volume of the buoyancy-driven submersible and in thermal communication with the plurality of thermoelectric generators;
   a battery electrically connected to the plurality of thermoelectric generators; and
   a buoyancy control mechanism.

A further embodiment of the disclosure is a method for generating electrical power from a marine environment thermal gradient, which comprises:
providing a cable extending vertically between a lesser depth and a greater depth of a body of water;
providing a buoyancy-driven submersible that comprises:
   a hull comprising an exterior surface in contact with the water and an interior surface defining an internal volume of the buoyancy-driven submersible;
   a plurality of thermoelectric generators disposed on the interior surface of the hull;
   a phase change material disposed within the internal volume of the buoyancy-driven submersible and in thermal communication with the plurality of thermoelectric generators;
   a battery electrically connected to the plurality of thermoelectric generators; and
   a buoyancy control mechanism;
moving the buoyancy-driven submersible vertically in reciprocating motion between the lesser depth and greater depth of the body of water along the cable, wherein the body of water possesses a temperature gradient in the vertical direction of movement of the buoyancy-driven submersible;
generating electrical power from the plurality of thermoelectric generators of the buoyancy-driven submersible; and
storing electrical power generated by the plurality of thermoelectric generators in the battery of the buoyancy-driven submersible.

These and other embodiments involve the use of buoyancy-driven submersibles integrated with thermoelectric generators (TEGs) and a phase change material (PCM) to harness energy from ocean thermal gradients. The buoyancy-driven submersible is capable of extracting energy from ocean thermal gradients and converting it into electricity for diverse ocean power applications.

A “marine environment” can include, for example, an ocean, sea, lake, or other body of water having a depth that may exhibit a temperature gradient between the surface and a lower depth of the body of water.

Most of the sun's heat energy, upon reaching Earth, is absorbed by the uppermost centimeters of the ocean. This top layer warms up during daytime and cools down at night, losing heat to the atmosphere. Ocean waves, influenced by their intensity and surface currents creating turbulence, stir the water in this surface zone, allowing the heat to spread to deeper waters. This typically results in a consistent temperature throughout the top 100 m of the ocean. Beyond this actively mixed zone, the temperature tends to remain more consistent, unaffected by the day/night temperature fluctuations. Moving further into the depths of the oceans, the temperature decreases gradually. The ocean's surface layer, typically a few hundred meters deep, is warmer and less dense than the underlying deep ocean, where water is cold and dense. This density difference hinders mixing between these layers. As depth increases, the deep ocean's temperature gradually decreases. The thermocline, located between 400 m and 1000 m depth, marks a rapid temperature decline. Tropical and equatorial regions exhibit greater temperature variations compared to mid-latitude areas. Moreover, surface ocean temperatures remain relatively constant throughout the year. These conditions can be advantageous for systems and methods of the disclosure that utilize temperature gradients between surface and deep ocean water.

In some embodiments, the body of water may exhibit temperature differences between the surface and deep waters ranging from, for example, about 7° C. to about 30° C., depending on seasonal variations. Typical ocean gradients in low and middle latitudes are on the order of approximately 20° C. The body of water may include, for example, a depth of about 300 m or more, such as from about 300 m to about 1,000 m, including from about 300 m to about 500 m, or from about 500 m to about 1,000 m. The ocean has an annual storage potential of about 1.09×10¹⁹ MJ, where approximately 7.63×10¹⁷ MJ could be harnessed from thermal to electricity energy conversion devices having an efficiency of 7%, which represents a significant opportunity for harvesting energy.

Systems and methods of the disclosure comprise a cable extending vertically between a lesser depth and a greater depth of the body of water. The cable can be made of any appropriate material, such metallic wire or non-metallic fiber. In some embodiments, the cable comprises steel wire. In further embodiments, the cable can serve as a transmission line for delivering electricity from the buoyancy-driven submersible to another component that is either within or outside of the system.

The buoyancy-driven submersible is configured to travel vertically in reciprocating motion between the lesser depth and greater depth of the body of water along the cable. In some embodiments, the hull of the buoyancy-driven submersible has an annular cross section defining a hole extending vertically through the buoyancy-driven submersible and in which the cable is disposed. The buoyancy-driven submersible therefore travels along the cable as the submersible ascends or descends in the body of water. The cable can remain stationary as the buoyancy-driven submersible moves vertically relative to the stationary cable.

Travel of the buoyancy-driven submersible vertically in reciprocating motion refers to the ascending and descending movement of the submersible in repeated cycles while the submersible remains essentially geostationary. By remaining geostationary, the buoyancy-driven submersible does not travel laterally in significant distances across the body of water.

As used herein, the terms “vertical” or “vertically” are intended to include substantially vertical alignment of the cables or direction of travel of the buoyancy-driven submersible, taking into account variations to perfectly vertical alignment or movement that may arise due to, for example, slack in the cables and swaying of the buoyancy-driven submersible due to currents in the body of water as it ascends and descends along the cables.

In some embodiments, the system of the disclosure further comprises:
a top platform; and
a bottom platform positioned at a distance below the top platform and at a depth within a body of water;
wherein the cable extends vertically from the top platform to the bottom platform, and wherein the buoyancy-driven submersible is configured to travel vertically in reciprocating motion between the top platform and bottom platform along the cable.

In exemplary embodiments, the top platform is positioned to float on the surface of the body of water. The bottom platform may be positioned, for example, at a depth of from 300 m to 1000 m below the surface of the body of water.

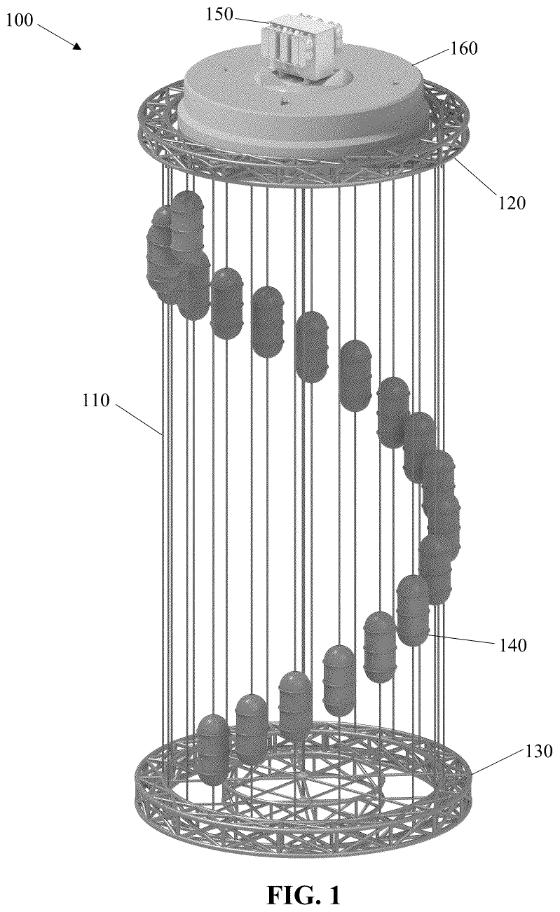

FIG. 1 illustrates an exemplary system 100 of the disclosure. The system comprises a plurality of cables 110 extending vertically between top platform 120 and bottom platform 130. Buoyancy-driven submersibles 140 are configured to travel vertically in reciprocating motion between the lesser depth and greater depth of a body of water along the cables and between the two platforms.

The buoyancy-driven submersibles generate power as they move vertically down in the ocean and back up to the sea surface, taking advantage of the temperature gradient of the sea with water depth. As shown in FIG. 1, more than one buoyancy-drive submersible may be provided. While the buoyancy-driven submersibles could be used to power an aquaculture farm, for instance, this is only one example of an application that the buoyancy-driven submersibles could provide power for. Other applications could include providing power for autonomous underwater vehicles (UAVs), offshore platforms, environmental sensors (i.e., thermometers, water quality monitors, pH sensors, pressure gauges, etc.), underwater energy storage (i.e., underwater batteries), water desalination stations, energy carrier production stations, and other applications.

In the embodiment shown in FIG. 1, the buoyancy-driven submersibles allow for substantially reciprocating and complementary operation of each submersible (i.e., a number of the submersibles move in opposite directions). In embodiments of the disclosure, buoyancy-driven submersibles may therefore be configured to travel vertically in reciprocating motion independently of each other such that one can descend or ascend in the body of water independently of the direction or speed of travel of the others.

Travel of the buoyancy-driven submersible vertically in reciprocating motion between the lesser depth and greater depth of the body of water can include one or more cycles of travelling from the surface of the body of water (such as from a top platform) to a lower depth (such as to a bottom platform) in the water and returning to the surface (or top platform). Some embodiments of methods of the disclosure comprise pausing movement of the buoyancy-driven submersible at a greater depth of the body of water (such as at the bottom platform) to facilitate discharging the PCM, and pausing movement of the buoyancy-driven submersible at a lesser depth of the body of water, or at or above the water surface (such as at the top platform), to facilitate charging the PCM. In some embodiments the buoyancy-driven submersible pauses movement within one or more cycles as discussed above for a longer period of time than it travels when ascending or descending in the body of water.

The buoyancy-driven submersible comprises:
a hull comprising an exterior surface configured to contact the water and an interior surface defining an internal volume of the buoyancy-driven submersible;
a plurality of thermoelectric generators disposed on the interior surface of the hull;
a phase change material disposed within the internal volume of the buoyancy-driven submersible and in thermal communication with the plurality of thermoelectric generators;
a battery electrically connected to the plurality of thermoelectric generators; and
a buoyancy control mechanism.

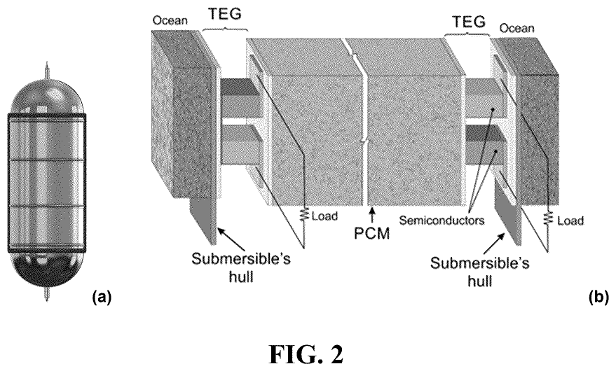

FIG. 2 illustrates (a) a buoyancy-driven submersible on the left, and on the right (b) a cross-section of a buoyancy-driven submersible with various internal components: TEGs can be disposed on the interior surface of the hull and a PCM in the center of the buoyancy-driven submersible, according to some aspects of the disclosure. In some embodiments of the disclosure, the buoyancy-driven submersible comprises one or more fins extending outwardly from the exterior surface of the hull to aid in heat transfer. The hull and fins may be constructed of a metallic material such as, for example, aluminum.

Embodiments of the disclosure can include a plurality of TEGs connected in series and deployed along the interior surface of the buoyancy-driven submersible's hull, creating a cylindrical layer. The PCM could be placed in a sealed vessel with a hollow cylinder geometry, designed and placed along the longitudinal axis of the vessel, which external surface is in contact with the TEG cylindrical layer. In such an instance, the TEGs can be disposed between the buoyancy-driven submersible's hull and the PCM vessel.

The buoyancy-driven submersible TEGs produce power as the submersible ascends or descends in the ocean or other body of water. Each individual buoyancy-driven submersible includes a hull, such as a metallic vessel, a buoyancy-control mechanism (which allows for the vertical movement of the submersible), a plurality of TEGs, and at least one PCM.

TEGs are solid-state devices that convert heat flux from a temperature gradient into electricity. The direct conversion of heat to electricity is possible through the Seebeck effect, defined as the thermoelectric phenomenon where a temperature differential across two dissimilar materials leads to a voltage difference generation. By maintaining a temperature difference between warmer and colder TEG sides, a heat flow is generated from the hot to the cold side. At least some of this heat is converted into electrical current. In many embodiments, a TEG comprises p-type and n-type materials that together constitute a thermocouple.

TEGs offer several benefits, including scalability, direct energy conversion, versatility, solid-state operation with no moving components, long lifespan, and high reliability in various systems and environments, which makes them a suitable choice for energy conversion applications. The TEGs generate power during the charging/melting of the PCM, while the buoyancy-driven submersible is near the surface of the body of water. Similarly, the TEGs generate power again as the buoyancy-driven submersible dives into the water, such as to a depth of about 800 m to 1000 m in some embodiments.

Power generation using TEGs can be boosted by connecting multiple units/components. For instance, TEGs may be provided in modules comprising, for example, about one-hundred TEGs. Two or more of such modules may be electrically connected in series to form a TEG network. Connection of the modules in series can increase power generation. In some embodiments, the plurality of TEGs includes several hundred or several thousand modules, with each module comprising, for example, about one-hundred TEGs.

In some embodiments, the TEGs may be in contact with the interior surface of the hull on one side and the PCM on the other, as shown in FIG. 2. The PCM may be located in the core of the buoyancy-driven submersible and act as a heat sink that maintains a relatively constant temperature on the internal side of the TEGs during the phase change. The TEGs may be connected in series to increase the voltage as the heat flows from the hot side to the cold side. As the buoyancy-driven submersible moves, the temperature of the hull and the side of the TEG connected to it varies with the water temperature during each movement cycle (a movement cycle being a complete up and down movement, returning to the same location).

As an example, a buoyancy-driven submersible with integrated TEGs and a PCM (with a phase transition temperature slightly below the ocean surface temperature) can maintain a temperature difference during operation at both sides of the TEGs once the PCM experiences the phase transition (at an almost constant temperature). Power will be generated by the TEGs by virtue of the temperature difference on both sides. When the buoyancy-driven submersible is near the ocean surface, the temperature in the ocean is warmer than the temperature of the PCM, generating a heat flow passing through the TEGs (thus inducing an electric current, and producing power) and reaching the PCM. From a thermal engine perspective, the ocean can be seen as the heat sources, while the PCM becomes a heat sink. Deep into the ocean, the temperature of the PCM (experiencing the transition) could be higher than the temperature of the ocean. In this case, heat is extracted from the PCM (heat source), passes through the TEGs (inducing a current in the opposite direction, i.e. changing the electric circuit's polarity, and producing power) and reaches the ocean (heat sink).

TEGs for use according to some embodiments of the disclosure advantageously meet one or more of the following criteria:
The Seebeck coefficient should be as high as possible to optimize energy conversion. The open-circuit voltage produced is directly proportional to both the Seebeck coefficient and the temperature difference across the TEG, represented as V_{seeback}=S_{PN}·ΔT. A higher Seebeck coefficient results in a greater voltage, which is valuable for enhancing energy conversion.
Electrical Conductivity (σ) should be maximized to minimize J oule heating arising from internal electrical resistances.
Thermal Conductivity (k) should be as low as possible. This ensures that heat is retained at the junctions, facilitating a larger temperature difference (ΔT) across the TEG and reduces thermal losses through the thermoelectric material.
Different thermoelectric materials excel at distinct temperature ranges. The application's operating temperature can be aligned with the TEG material's optimal temperature range.
The TEG should be capable of maintaining performance over the intended operating temperature range.
The TEG should present a high thermal stability and reliability to maintain its performance attributes during extended exposure to the intended operational temperatures. This is especially important if it is used in remote or locations with difficult accessibility.

Table 1 identifies several TEG materials suitable for harvesting ocean thermal gradients, according to embodiments of the disclosure.

TABLE 1
Exemplary TEGs

| | | | | Ø | |
|---|---|---|---|---|---|
| Positive/Negative | | T | P_{D} | (μW/ | |
| thermoelements | m | (° C.) | (W cm⁻²) | cm²K²) | zT |
| Li-doped | 32 | 27 | 9.77 × 10⁻⁴ | 0.01 | — |
| NiO/Ba_{0.2}Sr_{0.8}PbO₃ | | | | | |
| Fe₂V_{0.9}Ti_{0.1}Al/ | 18 | 7 | 0.077 | 0.98 | — |
| Fe₂VAl_{0.9}Si_{0.1} | | | | | |
| Fe₂V_{0.84}Ti_{0.16}A_{l0.97}Sb_{0.03}/ | 18 | 7 | 0.200 | 2.60 | — |
| Fe₂VAl_{0.9}Si_{0.07}Sb_{0.03} | | | | | |
| Si (p/n) | 50 | 27 | 0.280 | 3.11 | — |
| Zn₄Sb₃Bi_{0.3}Sb_{1.7}Te₃/ | 8 | 23 | 7.78 × 10⁻³ | 0.089 | — |
| PbSe_{0.5}Te_{0.5}Bi₂Te₃ | | | | | |
| p-AgSbTe_{1.85}Se_{0.15} | — | 27 | — | — | 0.55 |
| p-AgSb_{0.98}Cd_{0.02}Se₂ | — | 27 | — | — | 0.30 |
| P—AgBi_{0.5}Sb_{0.5}Se₂ | — | 27 | — | — | 0.25 |
| p-typeBI_{0.5}Sb_{1.5}Te₃ | — | 27 | — | — | 1.70 |
| P-typeBi_{0.3}Sb_{1.7-x}InₓTe₃ | — | 27 | — | — | 0.78 |
| CNT/PDMS | — | 18.1 | 3.100 | — | — |
| PEDOT:PSS/SWCNT | — | 20/293 | 0.028 | — | — |
| CNT/PEDOT:PSS | — | — | 1.52 × 10⁻⁸ | — | — |
| PbTe/Pb₁₋ₓEuₓTe | — | 20 | — | — | 2 |
| PbSeTe/PbTe | — | 20 | — | — | 2 |
| Bi₂Te₃ | — | 27 | — | — | 2.40 |
| Bi₂Te₃/Bi₂Te_{2.83}Se_{0.17} | — | 27 | — | — | 1.40 |
| Bi_{0.52}Sb_{1.48}Te₃ | — | 27 | — | — | 1.56 |
| Bi_{0.4}Sb_{1.6}Te₃ | — | 20 | — | — | 1.50 |
| Bi₂Te_{2.3}Se_{0.7} | — | 27 | — | — | 0.80 |
| Bi_{0.5}Sb_{1.5}Te₃ | — | 27 | — | — | 1.70 |
| N—Ag₂Se/P—Ag₂Te | — | 15 | 0.106 | — | — |
| Bi₂Te₃/Sb₂Te₃ | — | 20/293 | 15.24 | — | — |

In some embodiments, one or more of the plurality of TEGs comprise Bi₂Te₃, Bi_{0.4}Sb_{1.6}Te₃. PbSeTe and PbTe, PbTe and Pb₁₋ₓEuₓTe, Ag₂Se and p-Ag₂Te, or a carbon nanotube/poly(dimethylsiloxane) composite.

The PCM is disposed within the internal volume of the buoyancy-driven submersible and is in thermal communication with the plurality of TEGs. The PCM may be contained in a vessel that is within the internal volume of the buoyancy-driven submersible. The vessel may be constructed of any appropriate material that permits thermal communication of the PCM with the TEG network, including metallic materials such as aluminum and copper. In some embodiments, the PCM occupies about 20% or more of the internal volume of the buoyancy-driven submersible, such as about 30% or more, 40% or more, 50% or more, 60% or more, 70% or more, 80% or more, 90% or more, or 95% or more of the internal volume of the buoyancy-driven submersible.

PCMs release/store heat during the phase transition (i.e., charging/discharging), which is equal to the total amount of phase change enthalpy. The large variety of PCMs with multiple sets of thermophysical properties make them suitable for diverse thermal energy storage and temperature control applications. In addition to the high latent heat storage capacity, other advantageous characteristics of PCMs are thermal and chemical stability, high energy density, low price, no or reduced super-cooling and under-cooling, good recyclability, low vapor pressure, and good thermal conductivity.

Exemplary categories of PCMs include eutectic, inorganic, and organic (paraffin and non-paraffin) phase change materials. For optimal thermal performance of PCMs, high latent heat storage capacity and an efficient heat transfer during the phase transition are advantageous. The latent heat storage capacity in PCMs depends on the molecular packed density when crystalline in structure. The phase transition temperature depends on the force of the non-covalent bonds between the molecules.

In certain embodiments, the PCM has a transition temperature that is within the range of from about −4° C. to about 30° C. PCMs can advantageously be selected to possess a high-energy storage density, i.e., significant latent heat per volume unit, enabling it to absorb or release more thermal energy during its charging and discharging phases. The specific heat capacity and thermal conductivity are also two relevant properties to consider during a PCM selection. Chemical properties such as chemical stability, the super-cooling effect, corrosiveness, toxicity, and flammability can also be considered when selecting an appropriate PCM. A PCM for a specific application advantageously remains chemically and thermally stable after multiple freeze/melt cycles. Modern selection criteria also emphasize environmental considerations; the chosen material in many embodiments does not emit harmful or hazardous by-products that could negatively influence environmental conditions during its production, distribution, operation, or installation.

The volume expansion coefficient of PCMs is a relevant factor to consider, as PCMs transition between solid and liquid phases, leading to significant changes in volume due to density differences. A higher volume expansion coefficient results in more substantial volume changes. Additionally, sub-cooling affects the solidification of PCMs; when the sub-cooling value is zero (ΔT_{sub}=0), the PCM solidifies as the temperature drops below the solidification point. However, if the sub-cooling value is non-zero, the PCM may not solidify at its usual solidification temperature, influencing the PCM's transition from liquid to solid. Furthermore, stability is often a desirable attribute, as many PCMs can experience property changes with repeated phase change cycles, such as a reduction in latent heat.

Exemplary PCMs include, for example, aqueous salt solutions, fatty acids, acids, water, salt hydrates and eutectic mixtures, paraffins, sugar alcohols, nitrates, hydroxides, chlorides, carbonates, fluorides, and hydrocarbons. PCMs especially suitable for harvesting ocean thermal gradients include, for instance, water, paraffin waxes, fatty acids, acids such as formic acid, and hydrocarbons.

Table 2 identifies several organic PCMs suitable for harvesting ocean thermal gradients.

TABLE 2
Exemplary organic PCMs

| | Melting | Latent | Specific | Density | Thermal |
|---|---|---|---|---|---|
| | temper- | heat of | heat | (kg/m³) | conduc- |
| | ature | fusion | (kJ | (solid/ | tivity |
| PCM | (° C.) | (kJ/kg) | kg/K) | liquid) | (W/m · K) |
| Tetradecane | 5.8 | 227 | — | 770 | — |
| Pentadecane | 9.9 | 163 | — | 775 | — |
| Hexadecane | 18 | 236 | — | 773 | — |
| Heptadecane | 21.700 | 167 | — | 773 | — |
| Octadecane | 28 | 241 | — | 775 | — |
| Caprylic acid | 16 | 171 | 1.485 | 901 (/) | 0.149 |
| Isopropyl | 11 | 100 | — | — | — |
| palmitate | | | | | |
| Isopropyl | 22.100 | 113 | — | — | — |
| stearate | | | | | |
| Methyl laureate | 5 | 201 | — | — | — |
| Methyl | 5.900 | 213 | — | — | — |
| tridecanoate | | | | | |
| Methyl | 19 | 214 | — | — | — |
| myristate | | | | | |
| Methyl | 19.200 | 212 | — | — | — |
| pentadecanoate | | | | | |
| Methyl | 29 | 199 | — | — | — |
| palmitate | | | | | |
| Methyl | 29.900 | 225 | — | — | — |
| heptadecanoate | | | | | |
| Vinyl stearate | 27 | 122 | — | — | — |
| Xylitol | 18.700 | 170 | — | — | — |
| pentapalmitate | | | | | |
| Dimethyl | 21 | 135 | — | — | — |
| sebacate | | | | | |
| Vinyl stearate | 27 | 122 | — | — | — |
| Polyethylene | 4.200 | 117.6 | — | — | — |
| glycol | | | | | |
| RT10 | 10 | 150 | — | 880 | — |
| MC24 | 24 | 162.4 | — | — | — |
| BSF26 | 26 | 110 | — | 350 | — |
| MC28 | 28 | 170.1 | — | — | — |
| RT18 | 18 | 225 | — | 880/770 | 0.200 |
| BioPCM | 25 | 175 | — | — | — |
| RT-25 | 26.600 | 232 | — | — | — |
| Micronal ® DS | 25.670 | 111.3 | 1.972 | — | — |
| 5001 X | | | | | |
| Rubitherm ® | 27.550 | 258.1 | 1.652 | — | — |
| RT 28 HC | | | | | |
| Paraffin wax | 28.200 | 245 | — | — | — |
| RT-27 | 27 | 179 | — | — | — |
| BioPCM | 29 | 210 | — | — | — |
| Q29/M91 | | | | | |
| RT-21 | 21 | 134 | — | — | — |
| RT22HC | 22 | 134 | — | — | — |
| Rubitherm | 18 | 250 | — | — | — |
| RT18HC | | | | | |
| PureTemp20 | 20 | 171 | 2.070 | 950/860 | 0.140 |
| PureTemp5 | 5 | 187 | 2.260 | 960/880 | 0.250 |
| PureTemp8 | 8 | 178 | 1.850 | 950/860 | 0.220 |
| PureTemp15 | 15 | 182 | 2.250 | 950/860 | 0.250 |
| PureTemp18 | 18 | 192 | 1.470 | 950/860 | 0.250 |
| PureTemp23 | 23 | 201 | 1.840 | 910/830 | 0.250 |
| PureTemp25 | 25 | 187 | 1.990 | 950/860 | 0.250 |
| PureTemp27 | 27 | 202 | 2.460 | 950/860 | 0.250 |
| PureTemp28 | 28 | 190 | 2.340 | 950/860 | 0.250 |
| PureTemp29 | 29 | 202 | 1.770 | 940/850 | 0.250 |
| Acetic acid | 16.700 | 205 | — | — | — |
| RT21HC | 21 | 190 | 2 | 880/770 | 0.200 |
| RT24 | 24 | 160 | 2 | 880/770 | 0.200 |
| RT25HC | 25 | 230 | 2 | 880/770 | 0.200 |
| RT26 | 26 | 180 | 2 | 880/770 | 0.200 |
| RT28HC | 28 | 250 | 2 | 880/770 | 0.200 |
| A18 | 18 | 155 | 2.180 | 765 | 0.220 |
| A19 | 19 | 150 | 2.180 | 765 | 0.220 |
| A20 | 20 | 160 | 2.200 | 770 | 0.220 |
| A21 | 21 | 160 | 2.200 | 770 | 0.220 |
| A22 | 22 | 160 | 2.200 | 785 | 0.180 |
| A23 | 23 | 155 | 2.200 | 785 | 0.180 |
| A24 | 24 | 155 | 2.220 | 790 | 0.180 |
| A25 | 25 | 150 | 2.220 | 785 | 0.180 |
| A26 | 26 | 230 | 2.220 | 790 | 0.210 |
| A27 | 27 | 250 | 2.220 | 768 | 0.220 |
| A28 | 28 | 265 | 2.220 | 789 | 0.210 |
| A29 | 29 | 225 | 2.220 | 810 | 0.180 |
| OM18P | 19 | 233 | 2.200 | 780/750 | — |
| CrodaTherm19 | 19.300 | 175 | 2.500 | 911/850 | 0.230 |
| CrodaTherm21 | 21 | 190 | 2.300 | 891/850 | 0.180 |
| CrodaTherm24 | 24.100 | 183 | 2.400 | 949/842 | 0.290 |
| CrodaTherm24W | 23.870 | 184 | 3.700 | 906/843 | 0.220 |
| CrodaTherm29 | 29 | 207 | 2.300 | 917/851 | 0.220 |
| CrodaThermME29D | 28.800 | 183 | — | 980 | — |
| CrodaThermME29P | 28.800 | 183 | — | 337 | — |
| Formic acid | 7.800 | 277 | — | 1227 | 0.200 |
| Glycerol | 18.800 | 159.6 | — | — | — |
| Cetane | 18 | 231 | — | — | — |
| PCM20 | 18-20 | 171 | — | 680-950 | 0.14-0.23 |
| PCM21 | 19-21 | 186 | — | 730-936 | 0.14-0.23 |
| PCM22 | 20-22 | 208 | — | 780-923 | 0.14-0.24 |
| PCM23 | 21-23 | 227 | — | 830-910 | 0.15-0.25 |
| PCM24 | 22-24 | 207 | — | 840-930 | 0.15-0.25 |
| Paraffin C15-C16 | 8 | 153 | 2.200 | — | — |
| Paraffin C14 | 4.500 | 165 | — | — | 0.150 |
| Paraffin C16-C18 | 20-22 | 152 | — | — | — |
| Propy | 10 | 186 | — | — | — |
| palmitate | | | | | |
| Pelargonic | 12.300 | 127 | — | — | — |
| Butyl stearate | 19 | 140 | — | — | — |
| Paraffin C13-C14 | 22-24 | 189 | 2.100 | — | 0.210 |
| Dimethyl | 21 | 120-135 | — | — | — |
| sebacate | | | | | |
| Undecylenic | 24.600 | 141 | — | — | — |
| Undecylic | 28.400 | 139 | — | — | — |
| Paraffin C18 | 28 | 244 | 2.160 | 814 | 0.150 |

Table 3 identifies several inorganic PCMs suitable for harvesting ocean thermal gradients.

TABLE 3
Exemplary inorganic PCMs

| | | | | | Thermal |
|---|---|---|---|---|---|
| | Melting | Latent | Specific | Density | conduc- |
| | temper- | heat of | heat | (kg/m³) | tivity |
| | ature | fusion | (kJ | (solid/ | (W/m · |
| PCM | (° C.) | (kJ/kg) | kg/K) | liquid) | K) |
| POCl₃ | 1.000 | 85 | — | — | — |
| H₂O | 0.000 | 333 | — | — | 0.598 |
| D₂O | 3.700 | 318 | — | — | 0.595 |
| SbCl₅ | 4.000 | 33 | — | — | — |
| H₂SO₄ | 10.400 | 100 | — | — | 0.260 |
| ICl(β) | 13.900 | 56 | — | — | — |
| MOF₆ | 17 | 50 | — | — | — |
| SO₃(α) | 17 | 108 | — | — | — |
| ICl(α) | 17.200 | 69 | — | — | — |
| P₄O₆ | 23.700 | 64 | — | — | — |
| H₃PO₄ | 26.000 | 147 | — | — | 0.434 |
| Cs | 28.300 | 15 | — | — | — |
| Ga | 30.000 | 80 | — | — | — |
| AsBr₃ | 30.000 | 38 | — | — | — |
| SnBr₄ | 30.000 | 28 | — | — | — |
| CaCl₂•6H₂O | 27.380 | 87.440 | — | — | 0.178 |
| KF•4H₂O | 18.500 | 231 | 1.840 | 1447 | — |
| FeBr₃•6H₂O | 21 | 105 | — | — | — |
| Mn(NO₃)₂•6H₂O | 25.500 | 148 | — | — | — |
| CaCl₂•6H₂O | 29 | 191 | — | — | — |
| FeBr₃•6H₂O | 27 | 105 | — | — | — |
| LiBO₂•8H₂O | 25.700 | 289 | — | — | — |
| CaCl₂•12H₂O | 29.800 | 174 | — | — | — |
| LiNO₃•2H₂O | 30 | 296 | — | — | — |
| K₂HPO₄•4H₂O | 18.500 | 231 | — | — | — |
| LiNO₃•3H₂O | 30 | 189 | — | — | — |
| S8 | 8 | 130 | 1.900 | — | 0.440 |
| S20 | 20 | 195 | 2.200 | — | 0.540 |
| LiClO₃•3H₂O | 8.100 | 253 | 1.350 | 1720 | — |
| S21 | 21 | 95 | — | 1530 | 0.540 |
| S22 | 22 | 93 | — | 1530 | 0.540 |
| S23 | 23 | 86 | — | 1530 | 0.540 |
| Climsel C23 | 23 | 148 | — | — | — |
| S24 | 24 | 77 | — | 1530 | 0.540 |
| S25 | 25 | 75 | — | 1530 | 0.540 |
| S27 | 27 | 80 | — | 1530 | 0.540 |
| NaCl•Na₂SO₄•10H₂O | 18 | 256 | — | — | — |
| ZnCl₂•3H₂O | 10 | — | — | — | — |
| K₂HPO₄•6H₂O | 14 | 109 | — | — | — |
| NH₄Cl•Na₂SO₄•10H₂O | 11 | 163 | — | — | — |

Table 4 identifies several eutectic PCMs suitable for harvesting ocean thermal gradients.

TABLE 4
Exemplary eutectic PCMs

| | Melting | Latent heat |
|---|---|---|
| | temperature | of fusion |
| PCM | (° C.) | (kJ/kg) |
| Lauric acid-capric acid (45/55) | 21 | 143 |
| Capric acid-palmitic acid (76.5/23.5) | 21.800 | 171.2 |
| Methyl stearate + cetyl stearate | 22.200 | 180 |
| Methyl stearate + methyl palmitate | 23.900 | 220 |
| Tetradodecanol + lauric acid | 24.500 | 90 |
| Capric + palmitate | 22.100 | 153 |
| Capric/stearic acid | 24.700 | 178.6 |
| Methyl stearate + cetyl palmitate | 28.200 | 189 |
| Caprylic acid + lauric acid | 3.800 | 151.5 |
| Triethylolethane + urea | 29.800 | 218 |
| Xylitol/palmitic acid | 18.800 | 170.1 |
| Erythritol/palmitic acid | 21.900 | 201.1 |
| Erythritol/myristic acid | 10.800 | 180.9 |
| Mn(NO₃)₂•6H₂O + 4 wt % MnCl₂•4H₂O | 22.100 | 121.1 |
| CaCl₂•6H₂O—CO(NH₂)₂ | 24.180 | 149.2 |
| 50% CaCl₂ + 50% MgCl₂•6H₂O | 25 | 95 |
| 40% CH₃COONa•3H₂O + 60% NH₂CONH₂ | 30 | 200.5 |
| 48% CaCl₂ + 4.3% NaCl + 0.4% KCl + 47.3% H₂O | 27 | 188 |
| 45% CaCl₂•6H₂O + 55% CaBr₂•6H₂O | 14.700 | 140 |
| 66.6% CaCl₂•6H₂O + 33.3% MgCl₂•6H₂O | 25 | 127 |
| 47% Ca(NO₃)₂•4H₂O + 53% Mg(NO₃)₂•6H₂O | 30 | 136 |
| 50% Na₂SO₄•10H₂O + 50% NaCl | 18 | — |
| Tetradecane (91.67%) + hexadecane (8.33%) | 1.700 | 156.2 |
| Tetrahidrofurano (THF) | 5 | 280 |
| Tetradecane + docosane | 1.5-5.6 | 234.33 |
| Tetradecane + genei cosane | 3.54-5.56 | 200.28 |
| Na₂SO₄ (31%) + NaCl (13%) + KCl (16%) + H₂O (40%) | 4 | 234 |
| Pentadecane + docosane | 7.6-8.99 | 214.83 |
| Pentadecane + heneicosane | 6.23-7.21 | 128.25 |
| C₅H₅C₆H₅ (26.5%) + (C₆H₅)₂O (73.5%) | 12 | 97.9 |
| Pentadecane + octadecane | 8.5-9.0 | 271.93 |
| Na₂SO₄ (32%) + NaCl (14%) + NH₄Cl (12%) + H₂O (42%) | 11 | — |
| Triethylolethane (38.5%) + water (31.5%) + urea (30%) | 13.400 | 160 |
| Na₂SO₄ (37%) + NaCl (17%) + H₂O (46%) | 18 | — |
| CaCl₂•6H₂O (45%) + CaBr₂•6H₂O (55%) | 14.700 | 140 |
| Capric (61.5%) + lauric acid (38.5%) | 19.100 | 132 |
| Capric (45%) + lauric acid (55%) | 21 | 143 |
| Capric (82%) + lauric acid (18%) | 19.1-20.4 | 147 |
| Capric (73.5%) + myrstic (26.5%) | 21.400 | 152 |
| Capric (75.2%) + palmitate (24.8%) | 22.100 | 153 |
| CaCl₂•6H₂O (66.7%) + Nucleat + MgCl₂•6H₂O (33.3%) | 25 | 127 |
| CaCl₂•6H₂O (50%) + MgCl₂•6H₂O (50%) | 25 | 95 |
| Ca(NO₃)•4H₂O (47%) + Mg(NO₃)₃•6H₂O (53%) | 30 | 136 |
| CH₃COONa•3H₂O (40%) + NH₂CONH₂ (60%) | 30 | 200.5 |
| CaCl₂ (48%) + NaCl (4.3%) + KCl (0.4%) + H₂O (47.3%) | 26.800 | 188 |
| C₁₄H₂₈O₂ (34%) + C₁₀H₂₀O₂ (66%) | 24 | 147.7 |
| Capric (86%) + stearate (13.4%) | 26.800 | 160 |
| CH₃CONH₂ (50%) + NH₂CONH₂ (50%) | 27 | 163 |
| Triethylolethane (62.5%) + urea (37.5%) | 29.800 | 218 |

PCMs disclosed herein may also include conventional PCMs enhanced with additional components or encapsulated to improve their thermal conductivity. For instance, PCMs may include nanoparticles (such as graphene nanoparticles, carbon nanotubes, and silver nanoparticles) or metal foams (such as graphite foam, nickel foam and copper foam) to enhance their thermal conductivity.

TEG and PCM material combinations may be selected based on the geographical location or temperature gradients encountered in the body of water of interest in which systems of the disclosure will be used. Table 5 provides exemplary selections of TEG and PCM materials for various regions. Within each row of Table 5, one or more PCM materials listed may be used in combination with one or more TEG materials listed.

TABLE 5
TEG and PCM Selections

| Depth | | | T | | |
|---|---|---|---|---|---|
| (m) | Location | Season | (° C.) | PCM | TEG |
| Up to | North | Summer | 26.44 | RT 18HC, RT21HC, | Bl_{0.5}Sb_{1.5}Te₃, |
| 1000 | Atlantic | | | RT 22HC, RT21, | PbTe/Pb₁₋ₓEuₓTe, |
| | | | | A20, A21, A22, A23, | PbSeTe/PbTe, |
| | | | | A24, Nextek 24D, | Bi₂Te₃, Bi_{0.5}Sb_{1.5}Te₃ |
| | | | | PCM24, OM18P, | |
| | | | | PureTemp 20, 23, | |
| | | | | CrodaTherm21, 24 | |
| | | Winter | 20.67 | Acetic acid, | Bi_{0.4}Sb_{1.6}Te₃, |
| | | | | n-Hexadecane, A18, | PbSeTe/PbTe, |
| | | | | Nextek 18D, | PbTe/Pb₁₋ₓEuₓTeZn₄Sb₃Bi_{0.3}Sb_{1.7}Te₃/ |
| | | | | MPCM 18D, | PbSe_{0.5}Te_{0.5}Bi₂Te₃, |
| | | | | PCM18, | CNT/PDMS, |
| | | | | PureTemp18 | PEDOT:PSS/SWCNT |
| Up to | South | Summer | 29 | n-Octadecane, | Bl_{0.5}Sb_{1.5}Te₃, |
| 1000 | Atlantic | | | RT 24, RT 25HC, | PbTe/Pb₁₋ₓEuₓTe, |
| | | | | RT 26, A24, A26, | PbSeTe/PbTe, |
| | | | | Nextek 24D | Bi₂Te₃, Bi_{0.5}Sb_{1.5}Te₃, |
| | | | | MPCM 24D | Fe₂V_{0.84}Ti_{0.16}A_{l0.97}Sb_{0.03}/ |
| | | | | PureTemp 25, 27, | Fe₂VAl_{0.9}Si_{0.07}Sb_{0.03} |
| | | | | CrodaTherm24 | |
| | | Winter | 18 | Caprylic acid, | CNT/PDMS, |
| | | | | Pentadecane, | Ag₂Se/P—Ag₂Te, |
| | | | | Heptadecane, | PEDOT:PSS/SWCNT |
| | | | | Ethyl palmitate, | |
| | | | | Capric-lauric acid + | |
| | | | | pentadecane (90:10), | |
| | | | | Isopropyl palmitate, | |
| | | | | Propyl palmitate | |
| Up to | Eastern | Summer | 29.21 | n-Octadecane, | BI_{0.5}Sb_{1.5}Te₃, |
| 1000 | Gulf of | | | RT 24, RT 25HC, | PbTe/Pb₁₋ₓEuₓTe, |
| | Mexico | | | RT 26, A24, A26, | PbSeTe/PbTe, |
| | | | | Nextek 24D, | Bi₂Te₃, Bi_{0.5}Sb_{1.5}Te₃, |
| | | | | MPCM 24D, | Fe₂V_{0.84}Ti_{0.16}A_{l0.97}Sb_{0.03}/ |
| | | | | PureTemp 25, 27, | Fe₂VAl_{0.9}Si_{0.07}Sb_{0.03} |
| | | | | CrodaTherm24 | |
| | | Winter | 26.45 | RT 18HC, RT21HC, | BI_{0.5}Sb_{1.5}Te₃, |
| | | | | RT 22HC, RT21, | PbTe/Pb₁₋ₓEuₓTe, |
| | | | | A20, A21, A22, A23, | PbSeTe/PbTe, |
| | | | | A24, Nextek 24D, | Bi₂Te₃, Bi_{0.5}Sb_{1.5}Te₃, |
| | | | | PCM24, OM18P, | Fe₂V_{0.84}Ti_{0.16}A_{l0.97}Sb_{0.03}/ |
| | | | | PureTemp 20, 23, | Fe₂VAl_{0.9}Si_{0.07}Sb_{0.03} |
| | | | | CrodaTherm21, 24 | |
| Up to | Western | Summer | 30 | n-Octadecane, | Bl_{0.5}Sb_{1.5}Te₃, |
| 1000 | Gulf of | | | RT 24, RT 25HC, | PbTe/Pb₁₋ₓEuₓTe, |
| | Mexico | | | RT 26, A24, A26, | PbSeTe/PbTe, |
| | | | | Nextek 24D, | Bi₂Te₃, Bi_{0.5}Sb_{1.5}Te₃, |
| | | | | MPCM 24D, | Fe₂V_{0.84}Ti_{0.16}A_{l0.97}Sb_{0.03}/ |
| | | | | PureTemp 25, 27, | Fe₂VAl_{0.9}Si_{0.07}Sb_{0.03} |
| | | | | CrodaTherm24 | |
| | | Winter | 16 | n-Pentadecane, | CNT/PDMS, |
| | | | | Paraffin C15, | n-Ag₂Se/P—Ag₂Te, |
| | | | | n-Tetradecane, | |
| | | | | Polyglycol E400, | |
| | | | | Propyl palmitate, | |
| | | | | Isopropyl palmitate | |
| Up to | North | Summer | 14 | n-Pentadecane, | n-Ag₂Se/p-Ag₂Te |
| 1000 | Pacific | | | Paraffin C15, | |
| | | | | Polyglycol E400, | |
| | | | | Propyl palmitate, | |
| | | | | Isopropyl palmitate | |
| | | Winter | 9 | n-Tetradecane, | Fe₂V_{0.84}Ti_{0.16}A_{l0.97}Sb_{0.03}/ |
| | | | | Formic acid, | Fe₂VAl_{0.9}Si_{0.07}Sb_{0.03}, |
| | | | | Paraffin C14, | Fe₂V_{0.9}Ti_{0.1}Al/ |
| | | | | n-Tetradecane | Fe₂VAl_{0.9}Si_{0.1} |
| Up to | Central | Summer | 14 | n-Pentadecane, | n-Ag₂Se/p-Ag₂Te |
| 1000 | Pacific | | | Polyglycol E400, | |
| | | | | Paraffin C15, | |
| | | | | Propyl palmitate, | |
| | | | | Isopropyl palmitate | |
| | | Winter | 11 | n-Tetradecane, | Fe₂V_{0.84}Ti_{0.16}A_{l0.97}Sb_{0.03}/ |
| | | | | Formic acid, | Fe₂VAl_{0.9}Si_{0.07}Sb_{0.03}, |
| | | | | Paraffin C14, | Fe₂V_{0.9}Ti_{0.1}Al/Fe₂VAl_{0.9}Si_{0.1}, |
| | | | | n-Tetradecane, | N-Ag₂Se/P—Ag₂Te |
| | | | | Propyl palmitate, | |
| | | | | n-Pentadecane | |
| Up to | South | Summer | 19 | Caprylic acid, | CNT/PDMS, |
| 1000 | Pacific | | | Pentadecane, | n-Ag₂Se/p-Ag₂Te, |
| | | | | Heptadecane, | PEDOT:PSS/SWCNT, |
| | | | | Ethyl palmitate, | PbSeTe/PbTe, |
| | | | | Capric-lauric acid + | PbTe/Pb₁₋ₓEuₓTe |
| | | | | pentadecane (90:10) | |
| | | | | Isopropyl palmitate, | |
| | | | | Propyl palmitate | |

In some embodiments, the TEG and PCM materials are selected from those listed in Table 6. Within each row of Table 6, one or more PCM materials listed may be used in combination with one or more TEG materials listed.

TABLE 6
TEG and PCM Selections

| | PCMs (based on | TEGs (based on |
|---|---|---|
| Zone | high latent heat) | high zT value) |
| North Atlantic | 1. OM18P | 1. PbSeTe/PbTe |
| | 2. PureTemp 23 | 2. Bi_{0.4}Sb_{1.6}Te₃ |
| | 3. CrodaTherm21 | 3. PbTe/Pb₁₋ₓEuₓTe |
| South Atlantic | 1. Acetic acid | 1. PbSeTe/PbTe |
| | 2. n-hexadecane | 2. Bi_{0.4}Sb_{1.6}Te₃ |
| | 3. RT 21 | 3. PbTe/Pb₁₋ₓEuₓTe |
| Eastern Gulf of | 1. RT25HC | 1. PbSeTe/PbTe |
| Mexico | 2. OM18P | 2. Bi_{0.4}Sb_{1.6}Te |
| | 3. PureTemp 23 | 3. PbTe/Pb₁₋ₓEuₓTe |
| Western Gulf of | 1. RT25HC | 1. PbSeTe/PbTe |
| Mexico | 2. OM18P | 2. Bi_{0.4}Sb_{1.6}Te₃ |
| | 3. PureTemp 23 | 3. PbTe/Pb₁₋ₓEuₓTe |
| North Pacific | 1. n-pentadecane | Ag₂Se/p-Ag₂Te |
| | 2. Formic acid | |
| | 3. Propyl palmitate | |
| Central Pacific | 1. n-pentadecane | Ag₂Se/p-Ag₂Te |
| | 2. Formic acid | |
| | 3. Propyl palmitate | |
| South Pacific | 1. Caprylic acid | 1. CNT/PDMS |
| | 2. Acetic acid | 2. Ag₂Se/p-Ag₂Te |
| | 3. n-Hexadecane | |

The buoyancy-driven submersible comprises a buoyancy control mechanism. In some embodiments, the buoyancy control mechanism comprises an internal bladder, an external bladder, and a fluid reservoir comprising a fluid for transfer between the internal and external bladders. The internal bladder is disposed in the internal volume of the buoyancy-driven submersible, such as within a compartment positioned within the internal volume of the internal volume of the buoyancy-driven submersible. The external bladder is positioned outside of the internal volume of the buoyancy-driven submersible that is defined by the interior surface of the hull, such that the external bladder is exposed to the water. The buoyancy-driven submersible may comprise a cap, dome or other cover that surrounds the external bladder, where the cap, dome or other cover comprises openings, such as holes or slits, which allow water to enter. The presence of such a cap, dome or other cover can improve the hydrodynamics of the buoyancy-driven submersible, such as by reducing drag forces.

The fluid in the buoyancy control mechanism may be transferred from the internal bladder to the external bladder and back to control the submersible's buoyancy. Exemplary fluids include, for example, hydraulic oil and compressed gas, such as compressed nitrogen or argon gas. In some embodiments, the buoyancy control mechanism further comprises a piston configured to transfer fluid between the fluid reservoir and the internal bladder; wherein the piston can be driven at least in part by volumetric expansion and contraction of the PCM that results from its phase transition. Additional embodiments include a pump configured to transfer fluid from the external bladder to the internal bladder or from the internal bladder to the external bladder. The buoyancy control mechanism may further comprise pipes, valves, and other components as appropriate.

The battery of the buoyancy-driven submersible is electrically connected to the plurality of TEGs and is charged by the electrical power generated by the TEG. The battery may power one or more components of the buoyancy control mechanism, such as a pump.

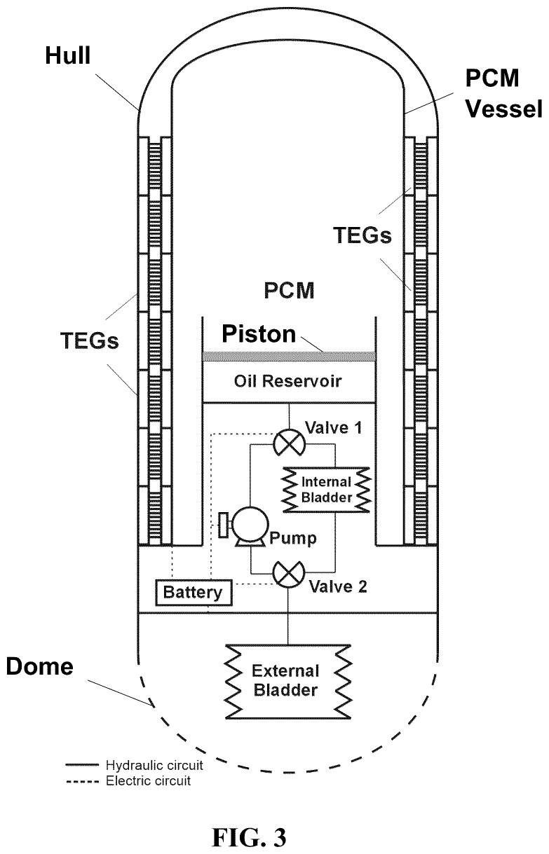

FIG. 3 illustrates a cross-section of an exemplary buoyancy-driven submersible, including its buoyancy control mechanism. The submersible utilizes a buoyancy engine for vertical movement in a body of water such as the ocean. Buoyancy adjustments can be achieved through a combination of hydraulic oil transfer and the volumetric expansion of the PCM during phase transition.

Near the ocean surface, the PCM absorbs energy and transitions from a solid to a liquid state. This melting process causes a volumetric expansion of the PCM, which drives a piston. The piston then forces oil through a three-way valve (Valve 1) into an internal bladder. Once the PCM is fully melted, Valve 1 redirects, connecting a hydraulic pump to an external bladder (via a second three-way valve, Valve 2). The pump then transfers oil from the external to the internal bladder, increasing the internal bladder's volume and pressure and changing the submersible's buoyancy from positive to negative, causing it to sink.

Upon reaching the bottom platform, Valves 1 and 2 close. The buoyancy-driven submersible remains at the bottom while the PCM releases energy and solidifies. During this solidification, the PCM contracts, reducing the pressure in the oil reservoir.

When the buoyancy-driven submersible is required to ascend to the ocean surface for PCM recharging (melting), Valve 2 opens, connecting the internal and external bladders. The higher pressure in the internal bladder drives oil into the external bladder. As the external bladder fills, the submersible's buoyancy shifts from negative to positive, initiating its ascent to the ocean surface, and the cycle repeats. The external bladder is positioned outside of the interior volume of the buoyancy-driven defined by the hull. The dotted lines surrounding the external bladder illustrate a dome that comprises openings, such as holes or slits, which allow water to enter the dome and contact the external bladder.

In some embodiments, such as the system illustrated in FIG. 1, the system of the disclosure further comprises a docking 160 station configured to facilitate extracting electrical power from the battery of the buoyancy-driven submersible and transferring the electrical power to a central system battery 150. The system may further comprise a transmission line configured to deliver electrical power from the central system battery to a power consumption application. For example, the docking station and central system battery may be disposed on the top platform of a system of the disclosure as in FIG. 1, and the transmission line may extend from the central system battery to the power consumption application.

### EXAMPLES

These Examples analyze performance of systems and methods of the disclosure through detailed thermodynamic assessments and computational fluid dynamics (CFD) modeling focused on heat transfer. The analyses consider real-world ocean temperature profiles and illustrate the interaction between TEGs and PCMs to optimize energy extraction. The evaluation encompasses several key performance metrics, including power output, energy efficiency, and overall system reliability. Preliminary results confirm the potential of this innovative technology to provide a continuous and reliable power source for marine applications.

### Example 1

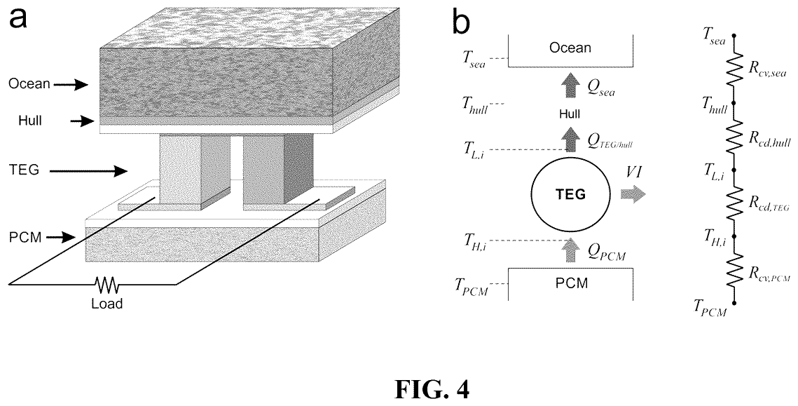

FIG. 4 illustrates in (a) a cross section of a portion of a buoyancy-driven submersible, and in b) a heat flow diagram through that portion of the buoyancy-driven submersible, according to some aspects of the disclosure. Using the nomenclature shown in FIG. 4 panel b), the heat transfer to the PCM may be calculated:

$${Q}_{PCM} = \frac{{T}_{PCM} - {T}_{Hi}}{{R}_{cv , PCM}} ,$$

and the heat transfer to the ocean may be calculated:

$${Q}_{sea} = \frac{{T}_{Li} - {T}_{sea}}{{R}_{cv , sea} + {R}_{cd , hull}}$$

$$where : {R}_{cd , hull} = ln ( \frac{{D}_{TP} / 2}{{D}_{TP} / 2 - {H}_{hull}} ) \frac{1}{2 π {L}_{TP} {k}_{hull}}$$

$${R}_{cv , PCM} = \frac{1}{{h}_{in} {nA}_{TEG}}$$

$${R}_{cv , sea} = \frac{1}{{h}_{out} {nA}_{TEG}}$$

The power output may be calculated:

$${W}_{TEG} = \frac{{{S}^{2} ( {T}_{Hi} - {T}_{Li} )}^{2}}{{R}_{elec}}$$

and the efficiency may be calculated:

$$η = \frac{{W}_{TEG}}{{Q}_{PCM} + {Q}_{loss}} .$$

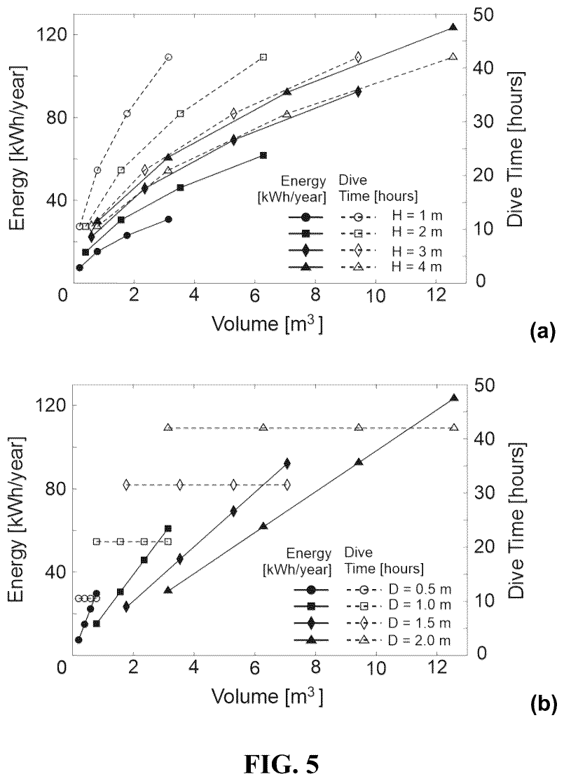

In modeling with these equations, exemplary buoyancy-driven submersibles may be able to generate about 0.8 Wh with a total volume of approximately 0.1 m³ during a movement cycle of approximately 2.8 hours to a total depth of approximately 1000 m. Other power levels could be generated, based on changes to the volume of the buoyancy-driven submersible, the PCM used, the depth moved during the movement cycle, and the temperature gradient of the ocean. Exemplary calculations are shown in graphs (a) and (b) in FIG. 5. Additional factors which could change the performance of the buoyancy-driven submersibles include: TEGs with better thermal conductivity and Seebeck coefficient, PCMs with higher thermal conductivity (for example, adding nanoparticles and high conductivity foams), increasing the surface area of the buoyancy-driven submersible, adding fins to increase the heat transfer coefficient, and/or hybridization with other renewable-based power generation technologies including wave energy, solar, and/or wind.

### Example 2

Geometric model. This Example analyzes the performance of a scaled-down TEG-PCM-based system. The system contains an inner cylinder filled with PCM, having an inner radius of 5.4 mm and an outer radius of 5.6 mm. The length of the cylinder is 20 mm. Individual TEG couples (about 20 individual TEGs) are attached along the outer circumference of the aluminum wall of this cylinder and in contact with the interior surface of another aluminum cylinder. PureTemp 20 was used as a PCM for this investigation because of its ideal phase change temperature (i.e., 20° C.), high latent heat capacity, non-toxicity, biodegradability, and long-term thermal stability. Table 7 illustrates the thermophysical properties of the PureTemp 20 PCM for both solid and liquid phases.

TABLE 7
Thermophysical properties of PureTemp 20 PCM

| | Melting | | Thermal | Specific | |
|---|---|---|---|---|---|
| | Point | Latent | Conductivity | Heat | Density |
| | (° C.) | Heat | (W/m · K) | (kJ/kg ·K) | (kg/m³) |
| PCM | (S/L) | (kJ/kg) | (S/L) | (S/L) | (S/L) |
| PureTemp 20 | 18/20 | 171 | 0.23/0.14 | 2.07/2.15 | 950/860 |

Since PCMs exhibit different thermophysical properties in their solid and liquid states, Table 7 provides both values for an accurate representation of their behavior during phase transitions. In Table 7, “S” and “L” represent the solid and liquid phase, respectively.

Bismuth Telluride (Bi₂Te₃) was used as the material for the TEGs due to its optimal thermoelectric properties at temperatures close to room temperature. Typical figure of merit (zT) values for optimized Bi₂Te₃-based alloys are on the order of 1.0-1.1 at ˜300K, which is significantly higher than other materials in this temperature range, which makes it best suitable for this application. The thermophysical properties of Bi₂Te₃ are shown in Table 8.

TABLE 8
Thermophysical properties of Bismuth Telluride (Bi₂Te₃)

| | Semiconductor | | Con- | Ceramic |
|---|---|---|---|---|
| | Constant | Variable | nector | Plate |
| Parameters | Property | Property | (Cu) | (Si) |
| Thermal | kₚ = kₙ | kₚ = kₙ | 350 | 130 |
| conductivity, k | 1.54 | 0.000029T² − | | |
| (W/m · K) | | 0.0119593T + | | |
| | | 4.809677 | | |
| Electrical | ρₚ = ρₙ | ρₚ = ρₙ | 1.695 × | — |
| conductivity, ρ | 1.03 × 10⁻⁵ | 10⁻⁶ (0.043542T − | 10⁻⁹ | |
| (Ω · m) | | 2.754139) | | |
| Seebeck | αₚ = −αₙ | αₚ = −αₙ | 6.5 × | — |
| coefficient, α | 2.0 × 10⁻⁵ | 10⁻⁶ (−0.0020257T² + | 10⁻⁶ | |
| (V/K) | | 1.423448T − | | |
| | | 44.953611) | | |

The temperature dependent variation in the properties of the TEGs couples has been considered. In Table 8, the subscripts p and n represent the p type and n type semi-conductor materials, respectively.

Governing equations and mathematical formulation. This outlines the essential physical principles underlying the study of the examined TEG-PCM based system. Simulations were conducted by coupling the Ansys Mechanical and Ansys Fluent using System coupling of Ansys 2024 R1 and applying key governing equations. To facilitate the implementation of the equation of the heat flow and continuity of the electric charge, the following assumptions were made:
1. The constant temperature of the outer wall of the TEGs, which is in contact with seawater, is considered to be 25° C.
2. Similarly, the constant temperature of the PCM is considered, which is at a temperature of 5° C.

The heat conduction equation for a thermoelectric device can be expressed as follows:

$$∇ . ( {k}_{i} ∇ T ) + \frac{{J}^{2}}{{ρ}_{i}} - {β}_{i} \vec{J} . ∇ T = 0$$

where: ρ represents the electrical conductivity, i subscript represents the connectors used in the couple of TEGs, ρ represents the p-type semiconductor, n used for the n-type semiconductor, k denotes the thermal conductivity, \vec{j} represents the local current density vector and its zero for the ceramic plates. In equation (1), the initial term on the left represents the Fourier heat conduction, while the second and third terms are indicative of Joule heating and the Thomson effect, respectively.

The electric potential of the TEGs is represented by the following equation:

$$∇ . ( σ ( ∇ ϕ - ( zT ) ∇ T ) ) = 0$$

where: α∇T represents the Seebeck electromotive force coming from the Seebeck effect. ϕ represents the electrical potential of the TEG and zT represents the coefficient of performance of the TEG.

The Thomson coefficient is directly proportional to the first derivative of the Seebeck coefficient with respect to temperature and is shown in the following equation:

$$β = T \frac{d α}{dT}$$

After getting the electrical potential, the current density can easily be calculated by the following equation:

$$\vec{J} = σ \vec{E} = σ ( - ∇ ϕ + α ∇ T )$$

Typically, the performance/effectiveness of a TEG is assessed using two key parameters: the power output (P) and conversion efficiency (η):

$$P = IV$$

$$η = \frac{P}{{Q}_{H}}$$

where Q_{H} represents the heat transferred to the hot side of the TEG and V represents the output voltage.

This study evaluates a novel three-dimensional TEG model against the traditional thermal resistance model, which is also briefly introduced here. It should be noted that the thermal resistance model does not account for the temperature and electric potential distributions within the TEG. Instead, it only considers the heat balances at the TEG's hot and cold ends. As a result, it is essential to define the thermal conductance (K), Seebeck coefficient (A), and total electrical resistance (R) for the p-n junction, as shown in the following equations:

$$R = \frac{{H}_{n}}{{σ}_{n} {S}_{n}} + \frac{{H}_{p}}{{σ}_{p} {S}_{p}}$$

$$A = - {α}_{n} + {α}_{p}$$

$$K = \frac{{k}_{n} {N}_{n}}{{H}_{n}} + \frac{{k}_{p} {N}_{p}}{{H}_{p}}$$

$$with {H}_{n} = {H}_{2} = {H}_{p} , {N}_{n} = {N}_{p} = {M}_{2} \times {N}_{2} ,$$

where H represents the height of thermoelectric legs, N represents the cross-sectional area of semiconductor material and M represents the geometric length parameter used to define the cross-sectional area of thermoelectric legs.

The following governing equations represent the transient melting heat transfer in the PCM. The energy balance equation for the PCM is described by the following equation.

$$\frac{\partial ( ρ h )}{\partial t} = ∇ . ( k ∇ T ) - {S}_{E}$$

where S_{E} is the source term and represented by:

$${S}_{E} = \frac{\partial ( ρ ϕ Δ {H}_{L} )}{\partial t}$$

The enthalpy term (i.e., h) is obtained from the following equation:

$$h = {h}_{ref} + {\int }_{{T}_{ref}}^{T} {C}_{p} dT + ϕΔ {H}_{L}$$

where ΔH_{L} and C_{ρ} represents the latent heat of fusion and specific heat of the PCM, respectively, href represents the enthalpy at a specific reference temperature (i.e., T_{ref}).

Additionally, the melt fraction (A) represents the extent to which a computational cell has experienced phase change and is defined by:

$$A = \{ \begin{matrix}\frac{T - {T}_{Sol}}{{T}_{Liq} - {T}_{Sol}} & {T}_{Sol} < T < {T}_{Liq} \\ 0 & T < {T}_{Sol} \\ 1 & {T}_{Liq} < T\end{matrix}$$

A melt fraction value of 1 indicates that the entire computational cell has fully transitioned through a phase change, whereas a value of 0 means that none of the computational cell has experienced a phase change.

Boundary conditions. A constant temperature of 25° C. is applied to the external wall of the TEGs, which is assumed to be in contact with seawater. System coupling is used to integrate Ansys Mechanical and Ansys Fluent through the inner ceramic wall of the TEGs and the outer cylinder wall, which encloses the PCM. A zero-reference voltage is applied at one end of an external resistor connected to the copper connector of a single TEG couple. The thermal-electric module in Ansys Mechanical is used to simulate the TEGs, while the melting/solidification model in Ansys Fluent is used to simulate the behavior of the PCM. The top and bottom walls of both the TEGs and the PCM are considered insulated. The SIMPLE method is used for pressure-velocity coupling, and a first-order upwind scheme is used for the discretization of the momentum and energy equations. The initial temperature of the TEGs is considered to be 22° C., while it is 4° C. for the PCM for the charging/melting of the PCM and vice versa for the discharging/solidification of the PCM.

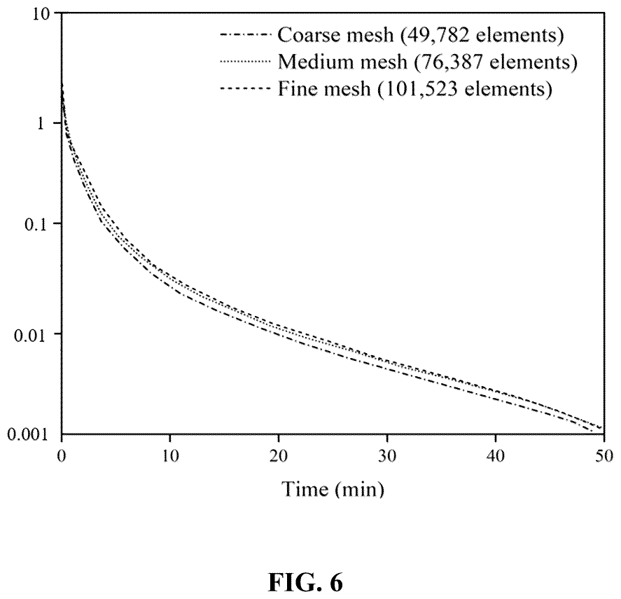

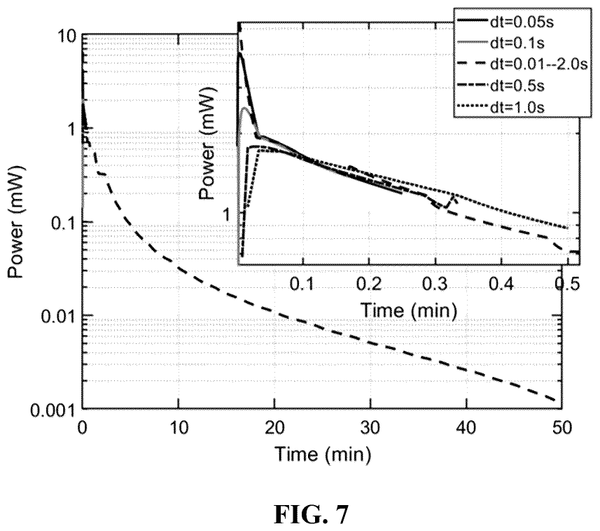

Grid and time independence study. The numerical analysis uses a structured grid to discretize the three-dimensional cross-section of TEG-PCM based system. A grid sensitivity analysis was conducted to ensure that the mesh does not affect the numerical results. For this purpose, three distinct grid sizes were employed: fine (101,523 elements), medium (76,387 elements), and coarse (49,782 elements). FIG. 6 illustrates the variations in the power produced by the TEGs during the charging/melting process of the PCM when the TEG-PCM-based system is considered near the sea surface under varying mesh conditions. The variation in the power production by TEGs is influenced by the grid sizes as shown in FIG. 6. As the elements count increases, the variation in power production becomes less pronounced. This study further investigates the effects of different time step sizes on numerical results across five time intervals (i.e., 0.05 seconds, 0.1 seconds, 0.5 seconds, 1 second and 0.01-2.0 seconds). FIG. 7 illustrates the fluctuations in power production across the different time steps. For computational perspective, this study utilizes 76,387 elements and adopts a time step of 0.1 s to balance the computational efforts and cost.

Model validation. Initially, a theoretical validation of the proposed model is performed by comparing a 1D steady-state simulation using the FEM technique in Ansys. This comparison focuses on the performance of the TEC1-12706 thermoelectric module, manufactured by the Tianjin Institute of Power Sources, China, as previously examined for experimental validation in another study. In both the p-type and n-type semiconductors of this module, the length of the elements is 1.6 mm, and the cross-sectional areas are 1.4×1.4 mm². The generator incorporates 127 thermocouples and is connected to a linear load resistance of 3.4 ohms. The chosen temperature range for validation aligns with experimental data from the TEC1-12706 thermoelectric module, ensuring direct comparability and validation accuracy. This range enables a meaningful evaluation of TEG performance, including heat transfer, power output, and efficiency under real-world operating conditions.

Initially, in the 1D simulation, the top and bottom surfaces are set to a constant temperature boundary condition, with the assumption that there is no heat loss from the other four sides of the legs. The simulation outcomes from Ansys, converging under various temperature ranges, were recorded. The numerical data on performance parameters from the current model exhibit nearly identical results as obtained from the experimental study. The maximum discrepancy between the experimental and numerical findings is under 5% with the present validation model.

Results: PCM charging. The temperature contour, liquid fraction contour, and electrical behavior of the TEG-PCM based system during charging/melting was observed. Over time, the heat transfers from the TEG's outer wall to the PCM inside the inner cylinder. Att=0, the PCM is uniformly at a low temperature. A s time progresses, the temperature starts increasing from the boundary of the PCM towards its core due to conductive heat transfer, creating a temperature gradient. By t=30 min, the PCM shows a significant temperature rise near the surface, progressing inward. Similarly, the PCM begins melting near the boundaries as it reaches its phase change temperature. At 3.3 minutes, an initial small melt region forms on the outer layer. This melt region expands with time. At t=30 min, a substantial portion of the PCM has melted at the boundary, while the center remains solid due to slower heat penetration and the poor thermal conductivity of the PCM.

Initially, when the temperature difference between the outer wall of the TEGs and the PCM is high, power and efficiency are at their maximum. However, as heat transfer occurs and the PCM temperature rises, the temperature difference decreases, leading to a steady decline in power and efficiency. A similar trend is observed for current and voltage. At the beginning, the temperature gradient drives a higher current and voltage. Over time, as the temperature difference diminishes, the current and voltage outputs also decline.

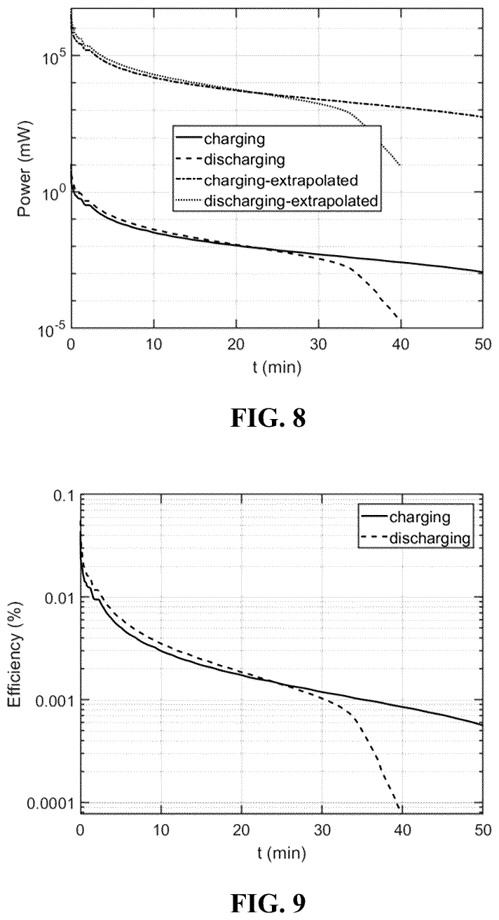

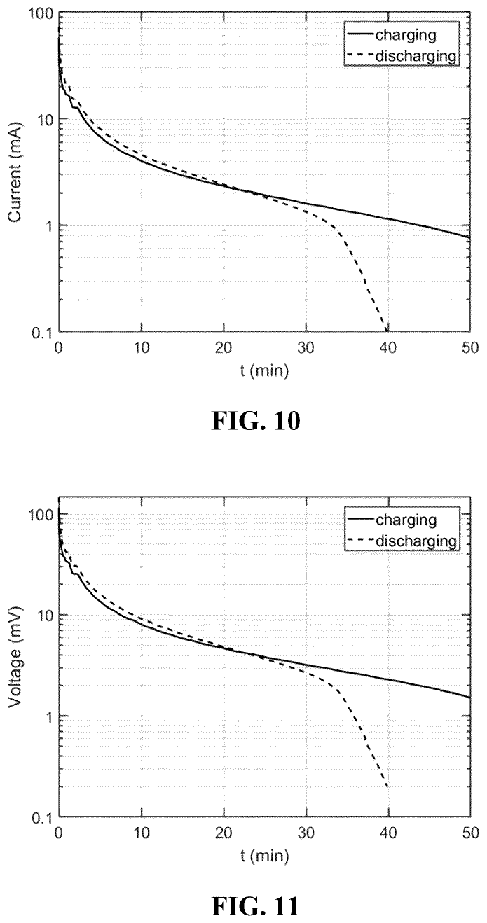

FIGS. 8-11 are graphs illustrating performance of the TEG-PCM based system during charging of PCM. FIG. 8 illustrates power generation by TEGs with respect to time. FIG. 9 illustrates efficiency of TEGs with respect to time. FIG. 10 illustrates current produced by TEGs with respect to time. FIG. 11 illustrates voltage produced by TEGs with respect to time.

Conclusion. This Example presents a scaled-down TEG-PCM based system that leverages ocean thermal gradients using TEGs and PCMs to address power needs in remote marine environments. The results highlight that the system effectively harnesses thermal energy, with TEGs initially producing higher power, current, voltage, and efficiency due to the larger temperature difference. Specifically, the TEGs demonstrated maximum power output and efficiency at the start of the PCM charging, driven by a high temperature difference that gradually decreased as the PCM absorbed the heat. At the beginning of the charging process, the temperature gradient between the TEGs and the PCM is maximized, resulting in optimal electrical output. However, as the PCM begins to melt and its temperature increases, this gradient diminishes, leading to a noticeable decline in TEG performance. Initially, the power output was high, but it decreased as the thermal gradient reduced over time. This dynamic performance underscores the TEGs' sensitivity to temperature variations and their critical role in the system's overall energy management strategy.

This phase change process ensured regulated energy release, critical for stable and continuous power supply. This combined approach, featuring dynamic temperature control and energy storage system, could enhance the autonomy of underwater vehicles, ocean sensors, and offshore platforms. The innovative integration of TEGs, PCMs, and buoyancy-driven submersible optimizes energy harvesting from varying thermal gradients, making this system a viable and sustainable solution for marine applications.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the disclosure, the Applicant in no way disclaims these technical aspects, and it is contemplated that the claimed invention may encompass one or more of the conventional technical aspects discussed herein. The following claims are hereby incorporated into this Detailed Description, with each claim standing on its own as a separate aspect, embodiment, or configuration.

We claim:

1. A system for generating electrical power from a marine environment thermal gradient, which comprises:
a cable extending vertically between a lesser depth and a greater depth of a body of water; and
a buoyancy-driven submersible configured to travel vertically in reciprocating motion between the lesser depth and greater depth of the body of water along the cable;
wherein the buoyancy-driven submersible comprises:
a hull comprising an exterior surface configured to contact the water and an interior surface defining an internal volume of the buoyancy-driven submersible;
a plurality of thermoelectric generators disposed on the interior surface of the hull;
a phase change material disposed within the internal volume of the buoyancy-driven submersible and in thermal communication with the plurality of thermoelectric generators;
a battery electrically connected to the plurality of thermoelectric generators; and
a buoyancy control mechanism.

2. The system of claim 1, which further comprises:
a top platform; and
a bottom platform positioned at a distance below the top platform and at a depth within a body of water;
wherein the cable extends vertically from the top platform to the bottom platform, and wherein the buoyancy-driven submersible is configured to travel vertically in reciprocating motion between the top platform and bottom platform along the cable.

3. The system of claim 2, wherein the top platform is positioned to float on the surface of the body of water.

4. The system of claim 2, wherein the bottom platform is positioned at a depth of from 300 m to 1000 m below the surface of the body of water.

5. The system of claim 1, wherein the hull of the buoyancy-driven submersible has an annular cross section defining a hole extending vertically through the buoyancy-driven submersible and in which the cable is disposed.

6. The system of claim 1, wherein one or more of the plurality of thermoelectric generators comprise Bi₂Te₃, Bi_{0.4}Sb_{1.6}Te₃, PbSeTe and PbTe, PbTe and Pb₁₋ₓEuₓTe, Ag₂Se and p-Ag₂Te, or a carbon nanotube/poly(dimethylsiloxane) composite.

7. The system of claim 1, wherein the phase change material has a transition temperature that is within the range of from about −4° C. to about 30° C.

8. The system of claim 1, wherein the phase change material is a paraffin wax, a fatty acid, formic acid, or a hydrocarbon.

9. The system of claim 1, wherein the phase change material occupies 20% or more of the internal volume of the buoyancy-driven submersible.

10. The system of claim 1, wherein the buoyancy control mechanism comprises an internal bladder, an external bladder, and a fluid reservoir comprising a fluid for transfer between the internal and external bladders.

11. The system of claim 10, wherein the fluid is hydraulic oil or compressed gas.

12. The system of claim 10, wherein the buoyancy control mechanism further comprises a piston configured to transfer fluid between the fluid reservoir and the internal bladder; wherein the piston is driven at least in part by volumetric expansion and contraction of the phase change material.

13. The system of claim 10, which further comprises a pump configured to transfer fluid from the external bladder to the internal bladder or from the internal bladder to the external bladder.

14. The system of claim 2, which further comprises a docking station configured to extract electrical power from the battery of the buoyancy-driven submersible to a central system battery.

15. The system of claim 14, which further comprises a transmission line configured to deliver electrical power from the central system battery to a power consumption application.

16. The system of claim 15, wherein the docking station and central system battery are disposed on the top platform and the transmission line extends from the central system battery to the power consumption application.

17. The system of claim 15, wherein the power consumption application is an aquaculture farm, an unmanned underwater vehicle, an offshore platform, an underwater energy storage device, a water desalination station, an energy carrier production station, or an environmental sensor.

18. The system of claim 2, which comprises two or more cables extending from the top platform to the bottom platform and two or more corresponding buoyancy-driven submersibles, wherein each buoyancy-driven submersible is configured to travel vertically in reciprocating motion, independently of each other, between the top platform and bottom platform along a corresponding cable.

19. A method for generating electrical power from a marine environment thermal gradient, which comprises:
providing a cable extending vertically between a lesser depth and a greater depth of a body of water;
providing a buoyancy-driven submersible that comprises:
a hull comprising an exterior surface in contact with the water and an interior surface defining an internal volume of the buoyancy-driven submersible;
a plurality of thermoelectric generators disposed on the interior surface of the hull;
a phase change material disposed within the internal volume of the buoyancy-driven submersible and in thermal communication with the plurality of thermoelectric generators;
a battery electrically connected to the plurality of thermoelectric generators; and
a buoyancy control mechanism;
moving the buoyancy-driven submersible vertically in reciprocating motion between the lesser depth and greater depth of the body of water along the cable, wherein the body of water possesses a temperature gradient in the vertical direction of movement of the buoyancy-driven submersible;
generating electrical power from the plurality of thermoelectric generators of the buoyancy-driven submersible; and
storing electrical power generated by the plurality of thermoelectric generators in the battery of the buoyancy-driven submersible.

20. The method of claim 19, which comprises pausing movement of the buoyancy-driven submersible at a greater depth of the body of water to discharge the phase change material, and pausing movement of the buoyancy-driven submersible at a lesser depth of the body of water or at or above the water surface to charge the phase change material.
